(19) United States
(12) Patent Application Publication
(10) Pub. No.: US 2026/0123451 A1
(43) Pub. Date: Apr. 30, 2026

(54) METHOD OF FABRICATING SEMICONDUCTOR PACKAGE

(71) Applicant: SAMSUNG ELECTRONICS CO., LTD., Suwon-si (KR)

(72) Inventor: Chanho JEONG, Suwon-si (KR)

(73) Assignee: SAMSUNG ELECTRONICS CO., LTD., Suwon-si (KR)

(21) Appl. No.: 19/366,011

(22) Filed: Oct. 22, 2025

(30) Foreign Application Priority Data
Oct. 25, 2024 (KR) 10-2024-0147642

(51) Int. Cl. H01L 21/48; H01L 23/00; H01L 23/498; H01L 25/00; H01L 25/18; H10B 80/00; H10D 80/30

(52) U.S. Cl. CPC H10W 70/093; H10W 90/00; H10B 80/00; H10D 80/30; H10W 90/401; H10W 90/724

(57) ABSTRACT

A method of fabricating a semiconductor package includes forming a first redistribution structure above a carrier substrate, forming an adhesive layer above the first redistribution structure, and disposing a mask having a plurality of preformed through holes on the adhesive layer. The method further includes removing portions of the adhesive layer exposed through the through holes to expose the underlying structure, forming a plurality of wiring posts electrically connected to the first redistribution structure within the through holes, removing the mask and the adhesive layer, and forming a first chip between the wiring posts and connected to the first redistribution structure. This method enables the formation of wiring posts without the use of a photoresist, reducing process complexity, time, and cost.

### CROSS-REFERENCE TO RELATED APPLICATIONS

This application claims the benefit of Korean Patent Application No. 10-2024-0147642, filed on Oct. 25, 2024, with the Korean Intellectual Property Office, the disclosure of which is incorporated herein by reference in its entirety.

### BACKGROUND

### 1. Field of the Invention

The present disclosure relates to a method for fabricating a semiconductor package.

### 2. Description of the Related Art

A demand for highly functional, high-speed, and smaller electronic components has been increasing due to developments in the electronics industry. In response to this growing demand, a method of laminating and mounting several semiconductor chips on and to one package wiring structure or laminating one package onto another package may be used. As an example, a package-in-package (PIP) type semiconductor package or a package-on-package (POP) type semiconductor package may be used.

Meanwhile, as semiconductor packages become highly integrated, the process of fabricating semiconductor packages becomes more complex, and the time and cost of fabricating semiconductor packages are increasing.

### SUMMARY

An aspect provides a simplified method for fabricating a semiconductor package.

An aspect also provides a method for fabricating a semiconductor package with reduced processing time and cost.

However, the goals to be achieved by example embodiments of the present disclosure are not limited to the objectives described above and other objects may be clearly understood from the following example embodiments by those skilled in the art.

According to an aspect, there is provided a method for fabricating a semiconductor package including forming a first redistribution structure above a carrier substrate, disposing a mask including a plurality of through holes above the first redistribution structure, forming a plurality of wiring posts electrically connected to the first redistribution structure within the plurality of through holes, removing the mask, and forming a first chip connected to the first redistribution structure between the plurality of wiring posts.

According to another aspect, there is provided a method for fabricating a semiconductor package including forming a first redistribution structure above a carrier substrate, forming an adhesive layer above the first redistribution package, disposing a mask in which a plurality of through holes are preformed on the adhesive layer, extending the plurality of holes by removing the adhesive layer exposed within the plurality of through holes, forming a plurality of wiring posts electrically connected to the first redistribution structure within the plurality of through holes, and removing the mask and the adhesive layer.

According to still another aspect, there is provided a method for fabricating a semiconductor package including forming a first redistribution structure above a carrier substrate, forming a seed layer on the first redistribution structure, forming an adhesive layer on the seed layer, disposing a mask including a plurality of through holes on the adhesive layer, extending the plurality of through holes to expose the seed layer within the plurality of through holes by removing the adhesive layer exposed within the plurality of through holes, forming a plurality of wiring posts electrically connected to the first redistribution structure within the plurality of through holes, removing the mask and the adhesive layer, patterning the seed layer using the plurality of wiring posts, forming a first chip connected to the first redistribution structure between the plurality of wiring posts, forming a molding film configured to surround the first chip and the plurality of wiring posts, forming a second redistribution structure connected to the plurality of wiring posts on the molding film, and forming a second chip connected to the second redistribution structure above the second redistribution structure.

Additional aspects of example embodiments will be set forth in part in the description which follows and, in part, will be apparent from the description.

### BRIEF DESCRIPTION OF THE FIGURES

These and/or other aspects, features, and advantages of the invention will become apparent and more readily appreciated from the following description of example embodiments, taken in conjunction with the accompanying drawings of which:

FIGS. 1 through 15 are drawings illustrating an intermediate process of a method for fabricating a semiconductor package according to example embodiments;

FIG. 1 is a drawing illustrating a state in which a first adhesive layer and a first redistribution structure are formed above a carrier substrate according to example embodiments;

FIG. 2 is a drawing illustrating a state in which a seed layer is formed on a first redistribution structure according to example embodiments;

FIG. 3 is a drawing illustrating a state in which a second adhesive layer is formed on a seed layer according to example embodiments;

FIG. 4 is a drawing illustrating a state in which a mask including a plurality of through holes is disposed above a first redistribution structure and a second adhesive layer according to example embodiments;

FIG. 5 is a drawing illustrating a state in which a second adhesive layer exposed through a plurality of through holes is removed according to example embodiments;

FIG. 6 is a drawing illustrating a state in which a plurality of wiring posts are formed within a plurality of through holes according to example embodiments;

FIG. 7 is a drawing illustrating a state in which a mask is removed according to example embodiments;

FIG. 8 is a drawing illustrating a state in which a second adhesive layer is removed according to example embodiments;

FIG. 9 is a drawing illustrating a patterned seed layer according to example embodiments;

FIG. 10 is a drawing illustrating a state in which a first chip is formed between a plurality of wiring posts according to example embodiments;

FIG. 11 is a drawing illustrating a state in which a molding film is formed according to example embodiments;

FIG. 12 is a drawing illustrating a state in which a second redistribution structure is formed on a molding film according to example embodiments;

FIG. 13 is a drawing illustrating a state in which a second chip is formed above a second redistribution structure according to example embodiments;

FIG. 14 is a drawing illustrating a state in which a carrier substrate and a first adhesive layer are removed according to example embodiments; and

FIG. 15 is a drawing illustrating a state in which an external connection terminal is formed below a first redistribution structure according to example embodiments.

### DETAILED DESCRIPTION

Before example embodiments of the present disclosure is described, terms or words used in the present disclosure and the accompanying claims are not to be limited to general definitions or dictionary definitions, and the terms and words are to be construed under a principle that an inventor may appropriately define a concept of a term in order to describe their invention in the best way. Accordingly, example embodiments described in the present disclosure and configurations illustrated in the accompanying drawings are merely the most desirable example embodiments and do not represent all of the technical spirit of the present disclosure, and it should be understood that various equivalents and modifications that may replace the example embodiments and configurations may be present at the time of filing the application of the present disclosure.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In the following descriptions, terms in a singular form include terms in a plural form unless an apparently and contextually conflicting description is present. Also, terms including “first” or “second” may be used to describe different elements however, the elements are not limited thereto and may be used to distinguish one element from the other. Within aspects of the inventive concept of the present disclosure, the first element may be named to be the second element, and similarly, the second element may be named to be the first element. In addition, in the drawings, such as shape and size of elements may be exaggerated for clarity.

In addition, it should be noted in advance that an expression such as an upper side, an upper surface, a lower side, a lower surface, a side surface, a front surface, or a rear surface is based on directions illustrated in the drawings and that the expression may be changed when a direction of a corresponding object is changed. In drawings, such as shape and size of elements may be exaggerated for clarity.

Hereinafter, example embodiments according to the inventive concept of the present disclosure will be described with reference to the drawings.

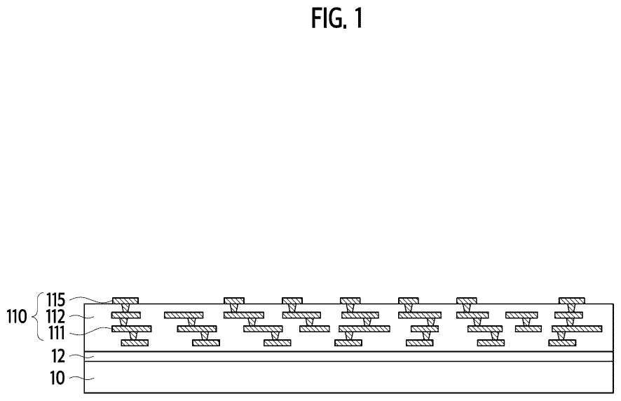

FIGS. 1 through 15 are drawings illustrating an intermediate process for describing a method for fabricating a semiconductor package according to example embodiments.

Referring to FIG. 1, the method for fabricating the semiconductor package according to example embodiments may include forming a first adhesive layer 12 and a first redistribution structure 110 above a carrier substrate 10. The first adhesive layer 12 and the first redistribution structure 110 may be sequentially formed above the carrier substrate 10. The first redistribution structure 110 may be formed on the first adhesive layer 12.

According to example embodiments, the carrier substrate 10 may be an insulating substrate including glass or a polymer or may be a conductive substrate including metal. The carrier substrate 10 may be a support substrate in which the first adhesive layer 12 and the first redistribution structure 110 and the like are arbitrarily formed during a process of fabricating the semiconductor package.

According to example embodiments, the first adhesive layer 12 may include a photoimageable dielectric (PID). As an example, the first adhesive layer 12 may include at least one of the photoimageable dielectric (PID), polybenzoxazole (PBO), a phenolic polymer, and a benzocyclobutene polymer.

According to example embodiments, the first redistribution structure 110 may be a wiring structure for a package. As an example, the first redistribution structure 110 may be a printed circuit board (PCB), a ceramic substrate, or an interposer. As another example, the first redistribution structure 110 may also be a wiring structure for a wafer level package (WLP) manufactured at a wafer level. As still another example, the first redistribution structure 110 may be a front redistribution layer (FRDL) of a fan-out package.

According to example embodiments, the first redistribution structure 110 may include a first redistribution metal layer 111, a first insulating film 112, and a bonding pad 115.

According to example embodiments, the redistribution metal layer 111 may be disposed within the first insulating film 112. The first redistribution metal layer 111 may include a wiring pattern and a wiring via connecting each wiring pattern. As an example, the first redistribution metal layer 111 may have a multi-layer structure of which two or more wiring patterns or two or more wiring vias are alternately laminated. The wiring pattern may be a part for a horizontal connection between conductive components and the wiring via may be a part for a vertical connection between conductive components. As an example, the wiring pattern may be extended in a horizontal direction parallel to the carrier substrate 10. The wiring via may connect wiring patterns spaced apart from each other in a vertical direction perpendicular to the carrier substrate 10.

According to example embodiments, the first redistribution metal layer 111 may include a conductive material. As an example, the first redistribution metal layer 111 may include copper (Cu), aluminum (Al), silver (Ag), tin (Sn), gold (Au), nickel (Ni), lead (Pb), titanium (Ti), or an alloy thereof, but it is merely an example.

According to example embodiments, when the first redistribution structure 110 is a printed circuit board (PCB), the first insulating film 112 may be made of at least one material selected from phenol resin, epoxy resin and polyimide. The first insulating film 112 may include at least one material selected from tetrafunctional epoxy, polyphenylene ether, epoxy/polyphenylene oxide, bismaleimide triazine (BT), Thermount, cyanate ester, and a liquid crystal polymer.

According to example embodiments, the first insulating film 112 may include photoimageable dielectric. As an example, the first insulating film 112 may include a photoimageable polymer. The photoimageable polymer, as an example, may be made of at least one of photoimageable polyimide, polybenzoxazole, a phenolic polymer, and a benzocyclobutene polymer. As another example, the first insulating film 112 may be made of a silicon oxide film, a silicon nitride film, or a silicon oxynitride film.

In FIG. 1, the insulating film 112 is illustrated as a single-layer film, however, the insulating film 112 may include a plurality of laminated insulating films. Each of the plurality of insulating films may surround the first redistribution metal layer 111 which will be described later.

Although not illustrated in the drawings, a surface of the first insulating film 112 may be covered by a solder resist. As an example, a passivation film may be formed on the surface of the first insulating film 112. The passivation film formed on the surface of the first insulating film 112 may protect the first redistribution metal layer 111 and other structures from external shock or moisture. The passivation film may include the solder resist. However, the technical spirit of the present disclosure is not limited thereto.

According to example embodiments, the bonding pad 115 may be electrically connected to the first redistribution metal layer 111. The bonding pad 115 may be disposed on the first insulating film 112. The bonding pad 115 may be exposed from the first insulating film 112. The bonding pad 115 may include a conductive material. As an example, the bonding pad 115 may include copper (Cu), aluminum (Al), silver (Ag), tin (Sn), gold (Au), nickel (Ni), lead (Pb), titanium (Ti), or an alloy thereof, but it is merely an example.

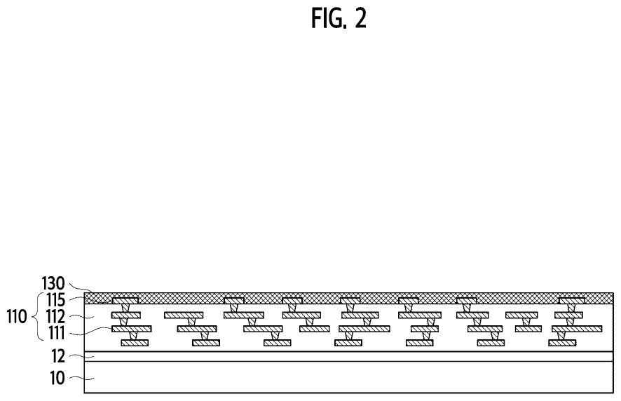

Referring to FIG. 2, the method for fabricating the semiconductor package according to example embodiments may include forming a seed layer 130 on the first redistribution structure 110. The seed layer 130 may cover the bonding pad 115. The seed layer 130 may be disposed on the first insulating film 112. The seed layer 130 may include a conductive material. As an example, the seed layer 130 may include copper (Cu), aluminum (Al), silver (Ag), tin (Sn), gold (Au), nickel (Ni), lead (Pb), titanium (Ti), or an alloy thereof, but it is merely an example.

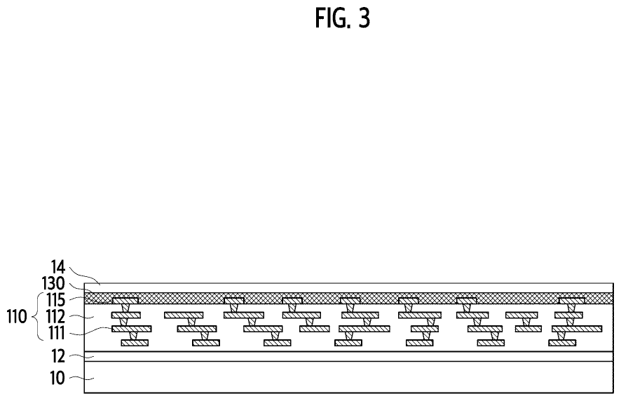

Referring to FIG. 3, the method for fabricating the semiconductor package according to example embodiments may include forming a second adhesive layer 14 on the seed layer 130. The second adhesive layer 14 may cover the seed layer 130. The second adhesive layer 14 may include a material identical to that of the first adhesive layer 12.

According to example embodiments, the second adhesive layer 14 may include a photoimageable dielectric (PID). As an example, the second adhesive layer 14 may include at least one of photoimageable polyimide, polybenzoxazole (PBO), a phenolic polymer, and a benzocyclobutene polymer.

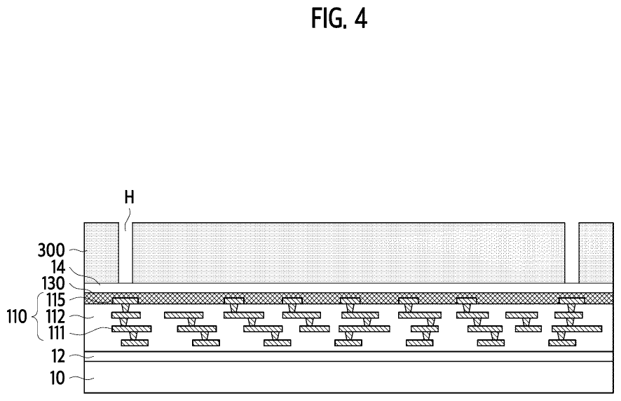

Referring to FIG. 4, the method for fabricating the semiconductor package may include disposing a mask 300 including a plurality of through holes H above the first redistribution structure 110 and the second adhesive layer 14. The plurality of through holes H may penetrate the mask 300. The plurality of through holes H may be preformed in the mask 300 before the mask 300 is disposed above the first redistribution structure 110.

According to example embodiments, the mask 300 may include at least one of photoimageable dielectric (PID) and glass. The mask 300 may not include a photoresist material. The mask 300 may have a single-layer structure. The mask 300 may include a material identical to that of the carrier substrate 10. As an example, each of the mask 300 and the carrier substrate 10 may include glass.

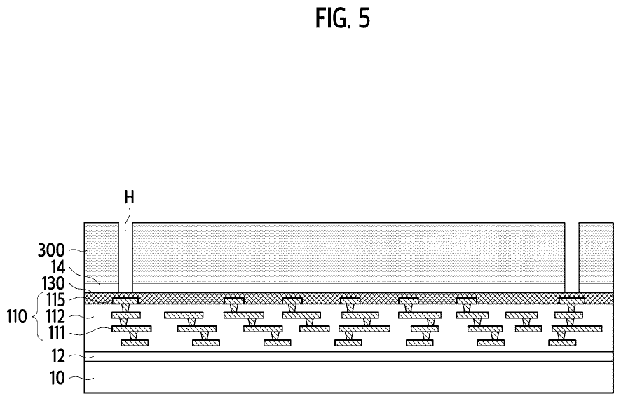

Referring to FIG. 5, the method for fabricating the semiconductor package according to example embodiments may include removing the second adhesive layer 14 exposed through the plurality of through holes H. The plurality of through holes H may be extended to expose the seed layer 130 within the plurality of through holes H by removing the second adhesive layer 14 exposed within the plurality of through holes H. The plurality of through holes H may be further extended by removing the second adhesive layer 14 exposed in the plurality of through holes H. The seed layer 130 may be exposed within the plurality of through holes H.

According to example embodiments, the second adhesive layer 14 exposed within the plurality of through holes H may be removed using a laser. As an example, the second adhesive layer 14 may be removed by irradiating insides of the plurality of through holes H with the laser.

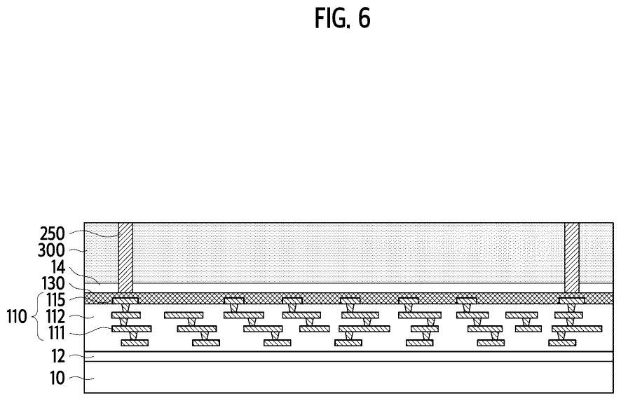

Referring to FIG. 6, the method for fabricating the semiconductor package according to example embodiments may include forming a plurality of wiring posts 250 in the plurality of through holes H. The plurality of wiring posts 250 may be formed within the plurality of through holes H including a portion at which the second adhesive layer 14 (of FIG. 4) is removed. The plurality of wiring posts 250 may be electrically connected to the first redistribution structure 110. As an example, the plurality of wiring posts 250 may be electrically connected to the first redistribution metal layer 111. The plurality of wiring posts 250 may be formed to penetrate the mask 300 and the second adhesive layer 14.

According to example embodiments, the plurality of wiring posts 250 may be formed on the seed layer 130. The plurality of wiring posts 250 may be formed to be in contact with the seed layer 130 within the plurality of through holes H. The plurality of wiring posts 250 may include a metal material such as titanium (Ti), copper (Cu), aluminum (Al), silver (Ag), tin (Sn), gold (Au), nickel (Ni), lead (Pb), or an alloy thereof.

Conventionally, to form a plurality of wiring posts, a mask layer including a photoresist material has been formed on a first redistribution structure and the mask layer has been patterned to make holes in which the plurality of wiring posts are formed. In addition, to form the plurality of wiring posts with sufficient extension lengths, coating with a photoresist material in multiple layers has been performed. Therefore, forming the plurality of wiring posts has required a large amount of time and cost as a process of coating with the photoresist material and patterning the photoresist material through exposure and development has been performed.

However, the method for fabricating the semiconductor package according to example embodiment of the present disclosure may simplify a process of forming the plurality of wiring posts 250 and reduce a time and a cost required in association therewith as the mask 300 including the plurality of through holes H (of FIG. 5) preformed therein is disposed above the first redistribution structure 110, and the plurality of wiring posts 250 are formed within the plurality of through holes H (of FIG. 5) in the method. In addition, since the mask 300 does not need to be manufactured each time to form the plurality of wiring posts 250 because the mask 300 may be reused several times by being disposed on and removed from the first redistribution structure 110 repeatedly, a time and a cost required in associated therewith may be reduced.

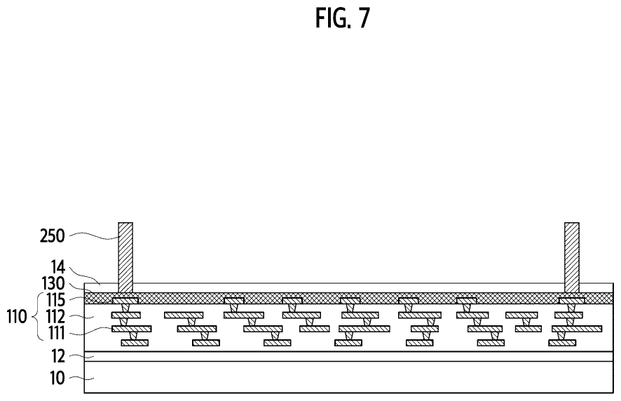

Referring to FIG. 7, the method for fabricating the semiconductor package according to example embodiments may include removing the mask 300 (of FIG. 6). The mask 300 (of FIG. 6) may be removed by a laser. When the mask 300 (of FIG. 6) is removed, the second adhesive layer 14 formed below the mask 300 (of FIG. 6) may be exposed.

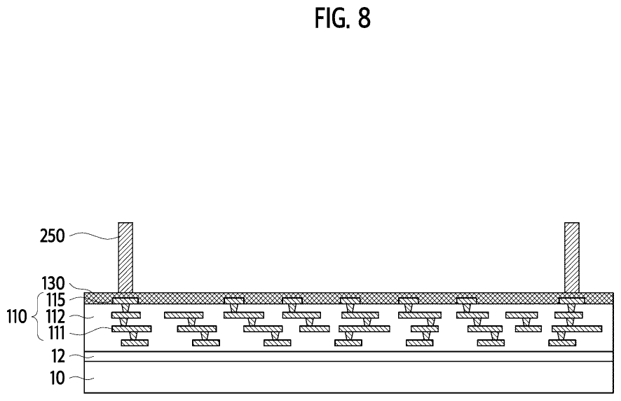

Referring to FIG. 8, the method for fabricating the semiconductor package according to example embodiments may include removing the second adhesive layer 14 (of FIG. 7). When the second adhesive layer 14 (of FIG. 7) is removed, the seed layer 130 formed below the second adhesive layer 14 (of FIG. 7) may be exposed.

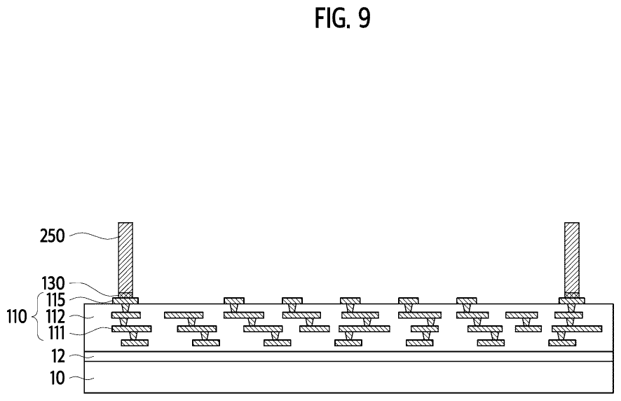

Referring to FIG. 9, the method for fabricating the semiconductor package according to example embodiments may include patterning the seed layer 130. The seed layer 130 may be patterned using the plurality of wiring posts 250. The seed layer 130 may be patterned to remove a remaining portion that does not overlap with the plurality of wiring posts 250. The seed layer 130 may be formed below the plurality of wiring posts 250. The seed layer 130 may be formed between the plurality of wiring posts 250 and the bonding pad 115.

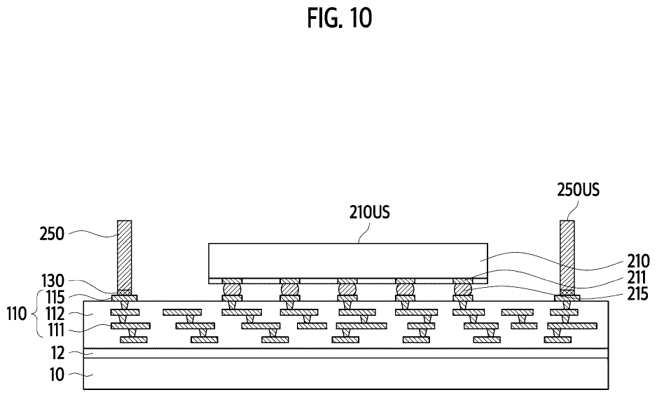

Referring to FIG. 10, the method for fabricating the semiconductor package according to example embodiments may include forming a first chip 210 between the plurality of wiring posts 250. The first chip 210 may be surrounded by the plurality of wiring posts 250. As an example, when viewed from a direction facing an upper surface 210US of the first chip, the plurality of wiring posts 250 may be disposed to surround the first chip 210 from an outward side of the first chip 210. The first chip 210 may be disposed at a central portion, and the plurality of wiring posts 250 may be disposed along an edge of the first redistribution structure 110 around the first chip 210.

According to example embodiments, the first chip 210 may be connected to the first redistribution structure 110. The first chip 210 may be bonded above the first redistribution structure 110 in a flip-chip bonding manner. A height of the upper surface 210US of the first chip may be smaller than heights of upper surfaces 250US of the plurality of wiring posts based on the first redistribution structure 110. The first chip 210 may be formed above the first redistribution structure 110 so that the upper surface 210US of the first chip is more adjacent to the first redistribution structure 110 than the upper surfaces 250US of the plurality of wiring posts. A thickness of the mask 300 (of FIG. 6) may be greater than a thickness of the first chip 210 in a direction in which the mask 300 (of FIG. 6) is laminated above the first redistribution structure 110. The thickness of the mask 300 (of FIG. 6) penetrated by the plurality of wiring posts 250 may be greater than the thickness of the first chip 210 of which the upper surface 210US is disposed below the plurality of wiring posts 250.

According to example embodiments, the first chip 210 may include a first lower connection pad 211. The first chip 210 may be bonded above the bonding pad 115 through a first bonding bump 215 disposed below the first lower connection pad 211. Each of the first lower connection pad 211 and the first bonding bump 215 may include a conductive material. As an example, each of the first lower connection pad 211 and the first bonding bump 215 may include copper (Cu), aluminum (Al), silver (Ag), tin (Sn), gold (Au), nickel (Ni), lead (Pb), titanium (Ti), or an alloy thereof, but it is merely an example. The first bonding bump 215, as an example, may have a pillar-structure or a solder ball structure, but it is merely an example.

According to example embodiments, the first chip 210 may be an integrated circuit (IC) of which hundreds to millions of semiconductor devices are integrated in one chip. The first chip 210 may include a logic chip. The first chip 210 may be an application processor (AP) such as a central processing unit (CPU), a graphics processing unit (GPU), a field-programmable gate array (FPGA), a digital signal processor, an encryption processor, a microprocessor, and a microcontroller, but it is merely an example. As an example, the first chip 210 may be a logic chip such as an analog-to-digital converter (ADC) or an application-specific integrated circuit (ASIC). As another example, the first chip 210 may be a memory chip such as a volatile memory (e.g., a dynamic random-access memory (DRAM)) or a non-volatile memory (e.g., a read-only memory (ROM) or a flash memory)). In addition, the first chip 210 may be a combination thereof.

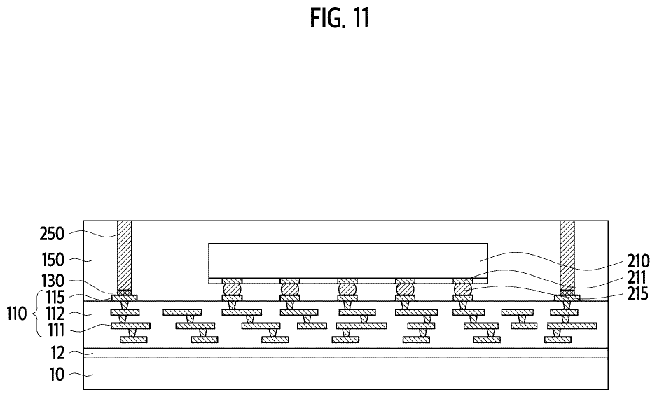

Referring to FIG. 11, the method for fabricating the semiconductor package according to example embodiments may include forming a molding film 150. The molding film 150 may surround the first chip 210 and the plurality of wiring posts 250. The molding film 150 may cover the first chip 210. The molding film 150 may not cover the upper surfaces 250US (of FIG. 10) of the plurality of the wiring posts 250.

According to example embodiments, the molding film 150 may include an insulating material. As an example, the molding film 150 may include an insulating polymer such as epoxy molding compound (EMC). As another example, the molding film 150 may include thermosetting resin such as epoxy resin and thermoplastic resin such as polyimide.

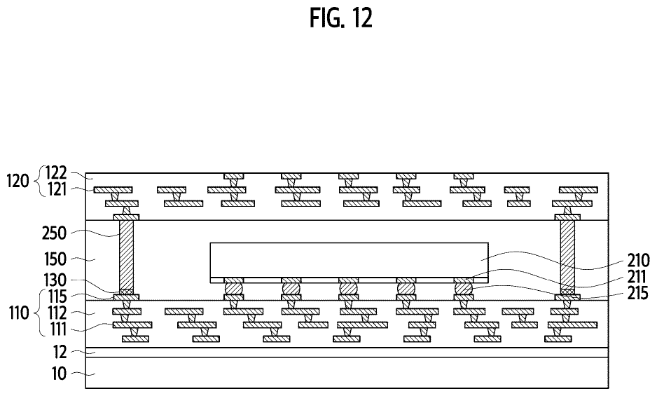

Referring to FIG. 12, the method for fabricating the semiconductor package according to example embodiments may include forming a second redistribution structure 120 on the molding film 150. The second redistribution structure 120 may be connected to the plurality of wiring posts 250. A second redistribution metal layer 121 of the second redistribution structure 120 may be electrically connected to the plurality of wiring posts 250. The plurality of wiring posts 250 may be extended between the first redistribution structure 110 and the second redistribution structure 120. The plurality of wiring posts 250 may connect the first redistribution structure 110 and the second redistribution structure 120.

According to example embodiments, the second redistribution structure 120 may include the second redistribution metal layer 121 and a second insulating film 122. Since being substantially identical to a description of the first redistribution metal layer 111 and the first insulating film 112, a description of the second redistribution metal layer 121 and the second insulating film 122 will be omitted.

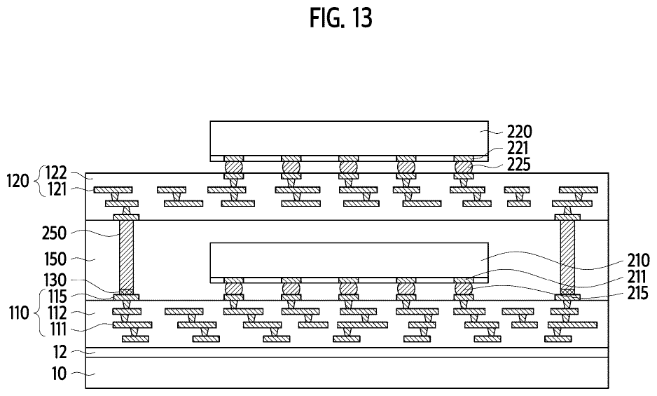

Referring to FIG. 13, the method for fabricating the semiconductor package according to example embodiments may include forming a second chip 220 above the second redistribution structure 120. The second chip 220 may be connected to the second redistribution structure 120. The second chip 220 may be bonded above the second redistribution structure 120 in a flip-chip bonding manner. The second chip 220 may include a second lower connection pad 221. The second chip 220 may be bonded above the second redistribution structure 120 through a second bonding bump 225 disposed below the second lower connection pad 221.

According to example embodiments, the second chip 220 may be an integrated circuit (IC) of which hundreds to millions of semiconductor devices are integrated in one chip. As an example, the second chip 220 may include a volatile memory (e.g., a dynamic random-access memory (DRAM)) or a non-volatile memory (e.g., a read-only memory (ROM) or a flash memory)). As another example, the second chip 220 may be an application processor (AP) such as a central processing unit (CPU), a graphics processing unit (GPU), a field-programmable gate array (FPGA), a digital signal processor, an encryption processor, a microprocessor, and a microcontroller, but it is merely an example. The second chip 220 may be a logic chip such as an analog-to-digital converter (ADC) or an application-specific integrated circuit (ASIC). In addition, the second chip 220 may be a combination thereof.

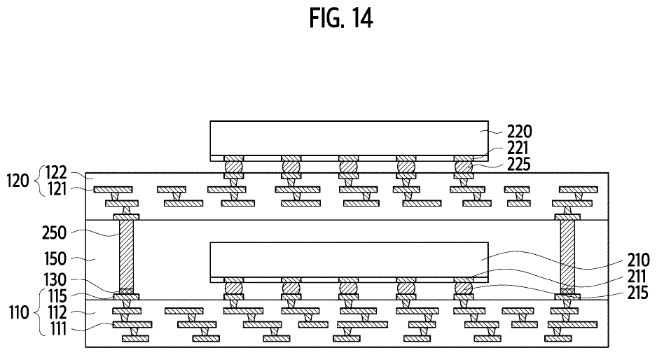

Referring to FIG. 14, the method for fabricating the semiconductor package according to example embodiments may include removing the carrier substrate 10 (of FIG. 13) and the first adhesive layer 12 (of FIG. 13).

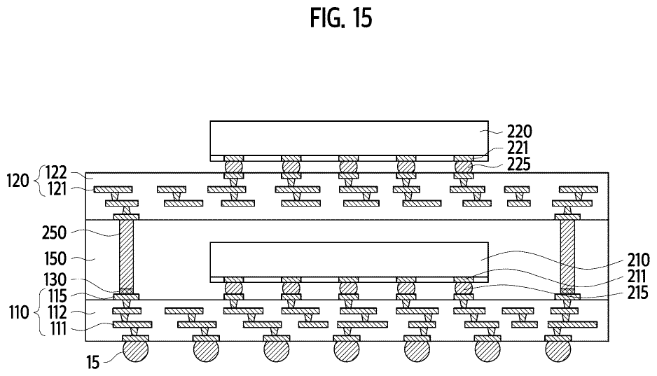

Referring to FIG. 15, the method for fabricating the semiconductor package according to example embodiments may include forming an external connection terminal 15 below the first redistribution structure 110. The external connection terminal 15 may be electrically connected to the first redistribution metal layer 111 of the first redistribution structure 110.

According to example embodiments, the external connection terminal 15 may include a solder ball or a solder bump. The external connection terminal 15 may include a micro bump. The external connection terminal 15 may have a spherical shape or an oval spherical shape, but it is merely an example. The number, spacing, or arrangement of external connection terminals 15, a shape of the external connection terminal 15, and the like are not limited to the drawings and may be modified according to a design. The external connection terminal 15, as an example, may include a tin (Sn), indium (In), bismuth (Bi), antimony (Sb), copper (Cu), silver (Ag), zinc (Zn), lead (Pb) and a combination thereof, but it is merely an example.

According to example embodiments, it is possible to simplify a method for fabricating a semiconductor package.

According to another example embodiments, it is possible to reduce a time and a cost required for a method for fabricating a semiconductor package.

While the present disclosure has been described in detail in connection with above example embodiments, however, the scope of the present disclosure is not limited thereto and it is to be understood by those skilled in the art that the present disclosure is intended to cover various modifications and equivalent arrangements within the spirit and scope of the appended claims. In addition, the above-described example embodiments may be implemented with some elements thereof removed, and each example embodiment may be implemented.

What is claimed is:

1. A method of fabricating a semiconductor package, the method comprising:
forming a first redistribution structure above a carrier substrate;
disposing a mask including a plurality of through holes above the first redistribution structure;
forming a plurality of wiring posts electrically connected to the first redistribution structure within the plurality of through holes;
removing the mask; and
forming a first chip connected to the first redistribution structure between the plurality of wiring posts.

2. The method of claim 1, wherein disposing the mask above the first redistribution structure comprises:
forming an adhesive layer above the first redistribution structure; and
disposing the mask on the adhesive layer.

3. The method of claim 2, wherein forming the plurality of wiring posts comprises:
removing the adhesive layer exposed through the plurality of through holes; and
forming the plurality of wiring posts within the plurality of through holes including a portion at which the adhesive layer is removed.

4. The method of claim 1, further comprising forming a second redistribution structure electrically connected to the plurality of wiring posts above the first chip and the plurality of wiring posts.

5. The method of claim 4, further comprising forming a molding film configured to surround the first chip and the plurality of wiring posts, after formation of the first chip and before formation of the second redistribution structure.

6. The method of claim 1, wherein a height of an upper surface of the first chip is lower than heights of upper surfaces of the plurality of wiring posts relative to the first redistribution structure.

7. The method of claim 1, wherein the mask comprises at least one of glass and silicon.

8. The method of claim 1, wherein the first redistribution structure comprises a bonding pad, and
the plurality of wiring posts are formed on the bonding pad.

9. The method of claim 1, wherein the mask has a single-layer structure.

10. The method of claim 1, wherein a thickness of the mask is greater than a thickness of the first chip in a direction in which the mask is laminated above the first redistribution structure.

11. The method of claim 1, wherein the carrier substrate and the mask include an identical material.

12. The method of claim 1, wherein the first chip is bonded above the first redistribution structure in a flip-chip configuration.

13. A method of fabricating a semiconductor package, the method comprising:
forming a first redistribution structure above a carrier substrate;
forming an adhesive layer above the first redistribution structure;
disposing a mask in which a plurality of through holes are preformed on the adhesive layer;
extending the plurality of through holes by removing the adhesive layer exposed within the plurality of through holes;
forming a plurality of wiring posts electrically connected to the first redistribution structure within the plurality of through holes; and
removing the mask and the adhesive layer.

14. The method of claim 13, wherein the mask does not comprise a photoresist material.

15. The method of claim 13, wherein removing the adhesive layer exposed within the plurality of through holes comprises removing the adhesive layer by irradiating insides of the plurality of through holes with a laser.

16. The method of claim 13, wherein the mask comprises at least one of glass and silicon.

17. The method of claim 13, further comprising forming a first chip connected to the first redistribution structure at an inward side of the plurality of wiring posts.

18. A method of fabricating a semiconductor package, the method comprising:
forming a first redistribution structure above a carrier substrate;
forming a seed layer on the first redistribution structure;
forming an adhesive layer on the seed layer;
disposing a mask including a plurality of through holes on the adhesive layer;
extending the plurality of through holes into the adhesive layer to expose the seed layer within the plurality of through holes by removing the adhesive layer exposed within the plurality of through holes;
forming a plurality of wiring posts electrically connected to the first redistribution structure within the plurality of through holes;
removing the mask and the adhesive layer;
patterning the seed layer using the plurality of wiring posts;
forming a first chip connected to the first redistribution structure between the plurality of wiring posts;
forming a molding film configured to surround the first chip and the plurality of wiring posts;
forming a second redistribution structure connected to the plurality of wiring posts on the molding film; and
forming a second chip connected to the second redistribution structure above the second redistribution structure.

19. The method of claim 18, wherein patterning the seed layer using the plurality of wiring posts comprises removing a remaining portion of the seed layer that does not overlap with the plurality of wiring posts.

20. The method of claim 18, wherein the first chip comprises a logic chip, and
the second chip comprises a memory chip.
